(19) United States
(12) Patent Application Publication
(10) Pub. No.: US 2012/0012875 A1
(43) Pub. Date: Jan. 19, 2012

(54) COMPONENT FOR LIGHT-EMITTING DEVICE, LIGHT-EMITTING DEVICE AND PRODUCING METHOD THEREOF

(75) Inventors: Yasunari OOYABU, Osaka (JP); Hironaka FUJII, Osaka (JP); Toshitaka NAKAMURA, Osaka (JP); Hisataka ITO, Osaka (JP)

(73) Assignee: NITTO DENKO CORPORATION, Osaka (JP)

(21) Appl. No.: 13/181,138

(22) Filed: Jul. 12, 2011

(30) Foreign Application Priority Data
Jul. 16, 2010 (JP) 2010-161710

(51) Int. Cl. H01L 33/50; H01L 21/66

(52) U.S. Cl. 257/98; 438/16; 257/E33.061; 257/E21.529

(57) ABSTRACT

A component for a light-emitting device includes a fluorescent layer that is capable of emitting fluorescent light and a housing that is connected to the fluorescent layer for housing a light-emitting diode.

### CROSS-REFERENCE TO RELATED APPLICATION

The present application claims priority from Japanese Patent Application No. 2010-161710 filed on Jul. 16, 2010, the contents of which are hereby incorporated by reference into this application.

### BACKGROUND OF THE INVENTION

### Field of the Invention

The present invention relates to a component for a light-emitting device, a light-emitting device, and a producing method thereof.

Conventionally, as a phosphor that receives blue light and emits yellow light, a YAG (yttrium aluminum garnet) based phosphor has been known. When the blue light is applied to the YAG based phosphor, white light can be obtained by color mixing of the applied blue light and the yellow light that the YAG based phosphor emits. Therefore, a white light-emitting diode that is capable of obtaining white light, for example, by covering a blue light-emitting diode with a YAG based phosphor to color mix blue light from the blue light-emitting diode and yellow light of the YAG based phosphor has been known.

As the white light-emitting diode, for example, a light-emitting device including a board, a semiconductor light-emitting device (LED device), and a phosphor ceramic board has been known. In addition, it has been known that a mold frame made of a reflecting member that reflects the light emitted from the LED device is provided in the light-emitting device and the mold frame surrounds the LED device (ref: for example, Japanese Unexamined Patent Publication No. 2010-27704).

By providing the mold frame therein, the mold frame can reflect the light that the LED device emits in all the directions and can emit the light in a desired direction.

### SUMMARY OF THE INVENTION

However, the white light-emitting diode with the mold frame is formed so that the board, the mold frame, the LED device, and the phosphor ceramic board are sequentially built up. Therefore, there is a disadvantage that its production process is complicated.

The optical characteristics of the white light-emitting diode with the mold frame obtained in this way are usually examined in the final stage of the production. Thereafter, the screening for non-defective products or defective products is performed and then the defective products are discarded.

In this case, when the white light-emitting diode obtained by the above-described method is examined and judged as a defective product, all the components used therein, for example, the board, the LED device, the phosphor ceramic board, and the mold frame are discarded, so that there is a disadvantage of having low yield rate and having poor production costs.

It is an object of the present invention to provide a component for a light-emitting device capable of producing a light-emitting device easily and achieving a decrease in production costs of the light-emitting device, a light-emitting device in which the component for a light-emitting device is used, and a producing method thereof.

A component for a light-emitting device of the present invention includes a fluorescent layer that is capable of emitting fluorescent light and a housing that is connected to the fluorescent layer for housing a light-emitting diode.

In the component for a light-emitting device of the present invention, it is preferable that the fluorescent layer is made of a ceramic that contains a phosphor and the housing is made of a ceramic that does not contain a phosphor.

In the component for a light-emitting device of the present invention, it is preferable that the melting point of the ceramic material forming the housing is higher than that of the ceramic material forming the fluorescent layer.

A light-emitting device of the present invention includes the above-described component for a light-emitting device.

It is preferable that the light-emitting device of the present invention includes a circuit board to which external electric power is supplied, a light-emitting diode that is electrically connected onto the circuit board and emits light based on electric power from the circuit board, and the component for a light-emitting device provided on the circuit board so as to house the light-emitting diode, wherein the upper end portion of the housing is positioned above the upper end portion of the light-emitting diode.

The method for producing a light-emitting device of the present invention includes the steps of electrically connecting a light-emitting diode onto the circuit board to which external electric power is supplied; screening for non-defective products or defective products by temporarily fixing the above-described component for a light-emitting device on the circuit board so as to house the light-emitting diode and so that the upper end portion of the housing is positioned above the upper end portion of the light-emitting diode, to examine the optical characteristics; and fixing the screened non-defective component for a light-emitting device.

In the component for a light-emitting device of the present invention, the fluorescent layer is connected to the housing, so that the step of separately building up the fluorescent layer and the housing is not necessary and therefore the light-emitting device can be easily produced.

In the component for a light-emitting device of the present invention, the fluorescent layer is connected to the housing before being provided on the light-emitting device, so that, in the production of the light-emitting device, the component for a light-emitting device can be temporarily fixed to examine the optical characteristics of the light-emitting device.

Therefore, according to the component for a light-emitting device of the present invention, the light-emitting device of the present invention using the component for a light-emitting device of the present invention, and further the producing method of the light-emitting device of the present invention, even when the light-emitting device is screened as a defective product, it is possible to remove the temporarily fixed component for a light-emitting device from the light-emitting device to be discarded. Furthermore, the removed component for a light-emitting device can be reused, so that an excellent yield rate can be ensured and the production costs can be reduced.

### BRIEF DESCRIPTION OF THE DRAWINGS

FIG. 1 shows a schematic configuration view of a first embodiment of a component for a light-emitting device of the present invention.

FIG. 2 shows a detailed perspective view of a disassembled form of the component for a light-emitting device shown in FIG. 1.

FIG. 3 shows schematic process drawings for illustrating one embodiment of a method for producing the component for a light-emitting device shown in FIG. 1:

(a) illustrating a step of preparing a first green sheet,

(b) illustrating a step of forming an opening in the first green sheet,

(c) illustrating a step of laminating a second green sheet on the first green sheet, and

(d) illustrating a step of sintering the first green sheet and the second green sheet at the same time.

FIG. 4 shows schematic process drawings for illustrating another embodiment of a method for producing the component for a light-emitting device shown in FIG. 1:

(a) illustrating a step of preparing the second green sheet,

(b) illustrating a step of sintering the second green sheet alone to obtain a fluorescent layer,

(c) illustrating a step of preparing the first green sheet that are provided with the opening,

(d) illustrating a step of sintering the first green sheet to obtain a housing, and

(e) illustrating a step of connecting the fluorescent layer to the housing.

FIG. 5 shows a schematic configuration view of another embodiment of the component for a light-emitting device of the present invention.

FIG. 6 shows a schematic configuration view of one embodiment of a light-emitting device of the present invention including the component for a light-emitting device shown in FIG. 1.

FIG. 7 shows schematic process drawings for illustrating a method for producing the light-emitting device shown in FIG. 6:

(a) illustrating a step of providing a light-emitting diode on a circuit board and electrically connecting the light-emitting diode to the circuit board,

(b) illustrating a step of screening for non-defective products or defective products by temporarily fixing the component for a light-emitting device on the circuit board so as to house the light-emitting diode and so that the upper end portion of the housing is positioned above the upper end portion of the light-emitting diode, to examine the optical characteristics,

(c) illustrating a step of fixing the screened non-defective component for a light-emitting device, and

(d) illustrating a step of providing a lens on the fluorescent layer of the component for a light-emitting device as required.

### DETAILED DESCRIPTION OF THE INVENTION

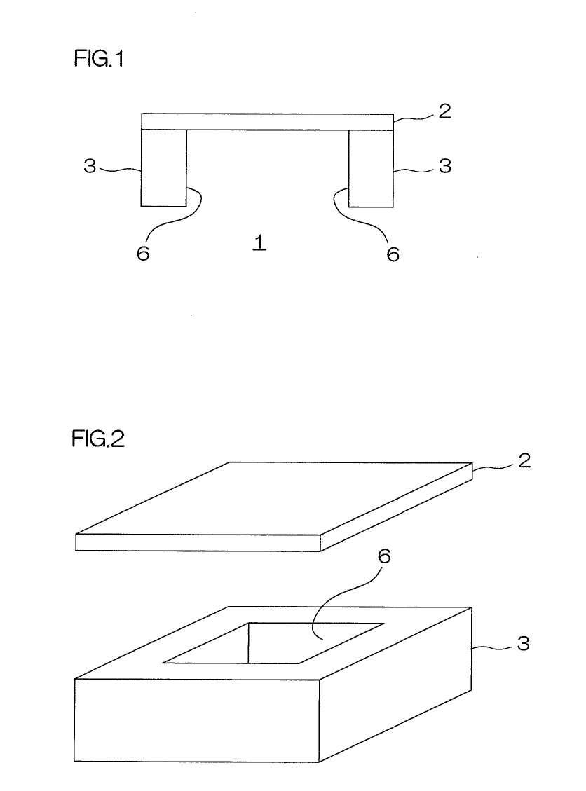

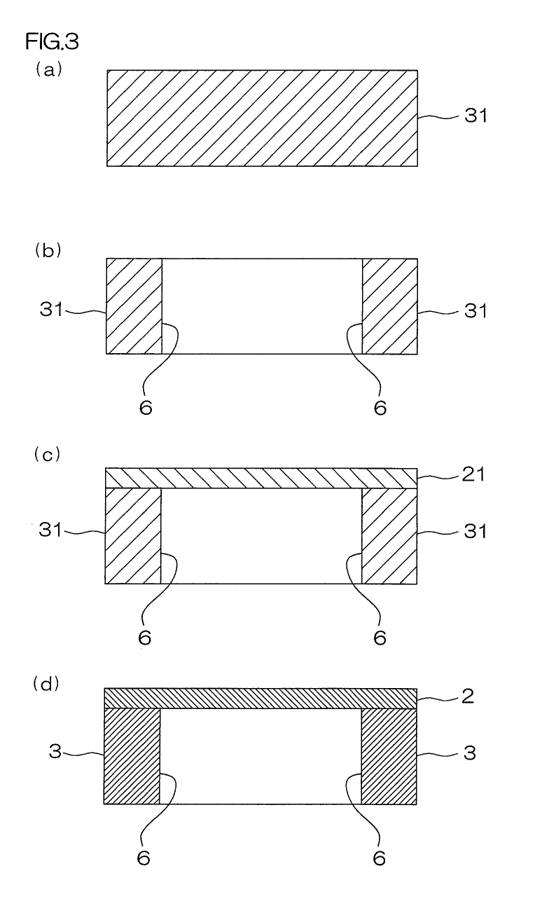

FIG. 1 shows a schematic configuration view of a first embodiment of a component for a light-emitting device of the present invention. FIG. 2 shows a detailed perspective view of a disassembled form of the component for a light-emitting device shown in FIG. 1. FIG. 3 shows schematic process drawings for illustrating one embodiment of a method for producing the component for the light-emitting device shown in FIG. 1.

In FIG. 1 and FIG. 2, a component 1 for a light-emitting device includes a fluorescent layer 2 and a housing 3 that is connected to the fluorescent layer 2.

The fluorescent layer 2 is a layer that is capable of emitting fluorescent light and transmitting light and is formed into a generally rectangular flat plate shape in plane view. The fluorescent layer 2 is provided, in a light-emitting device 11 (described later), so as to absorb the light generated from a light-emitting diode 13 (described later) to emit fluorescent light.

The fluorescent layer 2 contains a phosphor that is excited by absorbing a part or all of the light whose wavelength is in the range of 350 to 480 nm as an exciting light, and emits fluorescent light whose wavelength is longer than that of the exciting light, for example, in the range of 500 to 650 nm. In particular, a resin that contains a phosphor, a phosphor ceramic (phosphor ceramic plate), and the like are used therefor. The phosphor ceramic plate is preferably used for the fluorescent layer 2 from the viewpoint of heat dissipation.

That is, in the fluorescent layer 2, its temperature rises, for example, due to heat generation of an illuminant, so that its luminous efficiency may be reduced. However, the phosphor ceramic plate has excellent heat dissipation, so that the temperature rise of the fluorescent layer 2 can be prevented with the use of the phosphor ceramic plate and excellent luminous efficiency can be ensured.

The phosphor contained in the fluorescent layer 2 is selected appropriately in accordance with the wavelength of the exciting light. When, as an exciting light, for example, light of a near-ultraviolet light-emitting diode (wavelength in the range of 350 to 410 nm) or light of a blue light-emitting diode (wavelength in the range of 400 to 480 nm) is selected, examples of the phosphor include garnet type phosphor having a garnet type crystal structure such as Y₃Al₅O₁₂:Ce (YAG (yttrium aluminum garnet):Ce), (Y, Gd)₃Al₅O₁₂:Ce, Tb₃Al₃O₁₂:Ce, Ca₃Sc₂Si₃O₁₂:Ce, and Lu₂CaMg₂(Si, Ge)₃O₁₂:Ce; silicate phosphor such as (Sr, Ba)₂SiO₄:Eu, Ca₃SiO₄Cl₂:Eu, Sr₃SiO₅:Eu, Li₂SrSiO₄:Eu, and Ca₃Si₂O₇:Eu; aluminate phosphor such as CaAl₁₂O₁₉:Mn and SrAl₂O₄:Eu; sulfide phosphor such as ZnS:Cu,Al, CaS:Eu, CaGa₂S₄:Eu, and SrGa₂S₄:Eu; oxynitride phosphor such as CaSi₂O₂N₂:Eu, SrSi₂O₂N₂:Eu, BaSi₂O₂N₂:Eu, and Ca-α-SiAlON; nitride phosphor such as CaAlSiN₃:Eu and CaSi₅N₈:Eu; and fluoride-based phosphor such as K₂SiF₆:Mn and K₂TiF₆:Mn.

These phosphors can be used alone or in combination of two or more.

Garnet type phosphor is preferably used as the phosphor.

The fluorescent layer 2 can be produced, using the above-described phosphor, by a known method. In particular, for example, the fluorescent layer 2 (resin that contains a phosphor) can be obtained by mixing particles of the phosphor into the resin to be cured. Furthermore, for example, the fluorescent layer 2 (phosphor ceramic) can be obtained by using, for example, particles of the above-described phosphor as a ceramic material, and sintering the ceramic material.

The fluorescent layer 2 can be formed in a single-layer structure and furthermore, though not shown, can also be formed in a multi-layer structure in which a plurality (two or more) of layers are laminated.

The thickness (the sum of the thickness of each of the layers in the case of multi-layer structure) of the fluorescent layer 2 is in the range of, for example, 100 to 1000 μm, or preferably 200 to 700 μm, or more preferably 300 to 500 μm.

The thermal conductivity of the fluorescent layer 2 is, for example, 5 W/m·K or more, or preferably, for example, 10 W/m·K or more from the viewpoint of heat dissipation.

As shown in FIG. 2, the housing 3 is formed into a generally rectangular frame shape in plane view including an opening 6. The housing 3 is provided so as to house the light-emitting diode 13 (described later) in the opening 6 for dispersing and/or reflecting the light that the light-emitting diode 13 (described later) emits in all the directions to be emitted toward a desired direction and to transfer the heat generated by the light emission of the fluorescent layer 2.

The opening 6 (inner circumference) of the housing 3 is formed larger than the outer shape of the light-emitting diode 13 for housing the light-emitting diode 13 (described later).

The outer circumference shape of the housing 3 is formed in generally the same shape as that of the fluorescent layer 2 so that, in the connection between the fluorescent layer 2 and the housing 3, the outer circumference end edges of the fluorescent layer 2 and the housing 3 become flush with each other.

A material that can be used in the housing 3 is capable of dispersing and/or reflecting light and transferring the heat generated by the light emission of the fluorescent layer 2 without particular limitation. For example, a ceramic is used.

The housing 3 can be obtained, for example, by sintering a ceramic material.

Examples of the ceramic material, though not particularly limited, include aluminum oxide, yttrium oxide, zirconium oxide, titanium oxide, or further those doped with other elements.

The melting point of the ceramic material (the ceramic material that forms the housing 3) is in the range of, for example, 1500 to 3500° C., or preferably 1800 to 2250° C.

The melting point of the ceramic material (the ceramic material that forms the housing 3) is preferably higher than that of the above-described phosphor (the ceramic material that forms the fluorescent layer 2) and, in particular, is higher by, for example, 50 to 1000° C., or preferably 50 to 300° C. than that of the above-described phosphor (the ceramic material that forms the fluorescent layer 2).

When the melting point of the ceramic material forming the housing 3 is higher than that of the ceramic material forming the fluorescent layer 2, the housing 3 can become cloudy by preventing the over-sintering of the housing 3, so that excellent scattering efficiency and/or reflection efficiency of the light can be ensured.

When the melting point of the ceramic material forming the housing 3 is higher than that of the ceramic material forming the fluorescent layer 2, the housing 3 can be obtained as a porous ceramic (porous sintered body). When the housing 3 is the porous ceramic, light can be efficiently dispersed and/or reflected, so that excellent scattering efficiency and/or reflection efficiency can be ensured.

An example of the ceramic that forms the housing 3 is not limited to the porous ceramic and can include a ceramic that contains a known filler such as scattering particles and pigment. When such a ceramic is used, light can also be efficiently dispersed and/or reflected, so that excellent scattering efficiency and/or reflection efficiency can be ensured.

The reflectance of the housing 3 with respect to the light from the light-emitting diode 13 (described later) is, for example, 70% or more, or preferably 90% or more, or more preferably 95% or more.

In the following, a method for producing the above-described component 1 for a light-emitting device is described with reference to FIG. 3.

In this method, as shown in FIG. 3 (a), a first green sheet 31 is first prepared.

The first green sheet 31 is a ceramic before sintering that contains a ceramic material (the ceramic material that forms the housing 3) and is formed into a generally rectangular flat plate shape in plane view.

The first green sheet 31 is not particularly limited and can be produced, for example, by a known method in which a ceramic material, a known binder resin, dispersant, plasticizer, sintering additive, solvent, and the like are wet blended and an obtained slurry is subjected to casting and drying.

Next, in this method, as shown in FIG. 3 (b), the opening 6 having a generally rectangular shape in plane view is formed in the first green sheet 31. In this way, the first green sheet 31 is formed into a generally rectangular frame shape in plane view.

A method for forming the opening 6 is not particularly limited and, for example, a known method such as a boring process including punching, laser cutting, and the like can be used.

Next, in this method, as shown in FIG. 3 (c), a second green sheet 21 is laminated on the first green sheet 31 (the lower surface).

The second green sheet 21 is a ceramic before sintering that contains a phosphor (the ceramic material that forms the fluorescent layer 2) and is formed into a generally rectangular flat plate shape in plane view.

The second green sheet 21 is not particularly limited and can be produced, for example, by a known method in which a ceramic material, a known binder resin, dispersant, plasticizer, sintering additive, solvent, and the like are wet blended and an obtained slurry is subjected to casting and drying.

Thereafter, in this method, as shown in FIG. 3 (d), the first green sheet 31 and the second green sheet 21 are sintered at the same time. The sintering temperature at this sintering is in the range of, for example, 1500 to 1800° C., or preferably 1600 to 1750° C. and the sintering duration is in the range of, for example, 1 to 24 hours, or preferably 2 to 10 hours.

The component 1 for a light-emitting device including the housing 3 and the fluorescent layer 2 (the fluorescent layer 2 that is connected to the housing 3 so as to seal the one side end portion of the housing 3) can be obtained in this manner.

In the component 1 for a light-emitting device obtained in this way, the fluorescent layer 2 is connected to the housing 3, so that the step of separately building up the fluorescent layer 2 and the housing 3 is not necessary and therefore the light-emitting device 11 (described later) can be easily produced.

In the component 1 for a light-emitting device obtained in this way, the fluorescent layer 2 is connected to the housing 3 before being provided on the light-emitting device 11 (described later), so that, in the production of the light-emitting device 11 (described later), the component 1 for a light-emitting device can be temporarily fixed to examine the optical characteristics of the light-emitting device 11 (described later).

Therefore, according to the component 1 for a light-emitting device, even when the light-emitting device 11 (described later) is screened as a defective product, it is possible to remove the temporarily fixed component 1 for a light-emitting device from the light-emitting device 11 (described later) to be discarded. Furthermore, the removed component 1 for a light-emitting device can be reused, so that an excellent yield rate can be ensured and the production costs can be reduced.

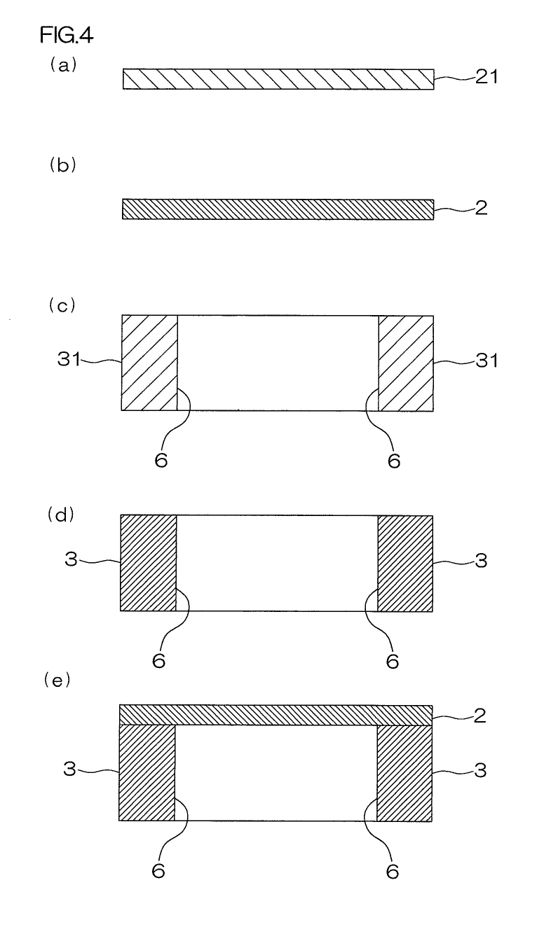

FIG. 4 shows schematic process drawings for illustrating another embodiment of a method for producing the component for a light-emitting device shown in FIG. 1.

In each figure to be described below, the same reference numerals are provided for members corresponding to each of those described above, and their detailed description is omitted.

In the above-described description, the first green sheet 31 and the second green sheet 21 are sintered at the same time to form the housing 3 and the fluorescent layer 2 at the same time. However, for example, the second green sheet 21 can be preliminarily sintered to form the fluorescent layer 2.

That is, in this method, as shown in FIG. 4 (a), the same second green sheet 21 as described above is first prepared.

Next, in this method, as shown in FIG. 4 (b), the second green sheet 21 is sintered alone. The sintering temperature at this sintering is in the range of, for example, 1500 to 1800° C., or preferably 1600 to 1750° C. and the sintering duration is in the range of, for example, 1 to 24 hours, or preferably 2 to 10 hours.

The fluorescent layer 2 is obtained in this manner.

Next, in this method, as shown in FIG. 4 (c), the first green sheet 31 (ref: FIG. 3 (a) and FIG. 3 (b)) that is provided with the opening 6 and is formed into a generally rectangular frame shape in plane view is separately prepared.

Next, in this method, as shown in FIG. 4 (d), the first green sheet 31 is sintered. The sintering temperature at this sintering is in the range of, for example, 1500 to 1800° C., or preferably 1600 to 1750° C. and the sintering duration is in the range of, for example, 1 to 24 hours, or preferably 2 to 10 hours.

The housing 3 is obtained in this manner.

Next, in this method, as shown in FIG. 4 (e), the fluorescent layer 2 (ref: FIG. 4 (b)) and the housing 3 (ref: FIG. 4 (d)) obtained by the above description are connected via an adhesive and the like as required.

When the adhesive is used, the application thickness thereof is in the range of, for example, 2 to 200 μm, or preferably 10 to 100 μm from the viewpoint of prevention of deformation and thermal conductivity.

The component 1 for a light-emitting device including the housing 3 and the fluorescent layer 2 (the fluorescent layer 2 that is connected to the housing 3 so as to seal the one side end portion of the housing 3) can be obtained in this manner.

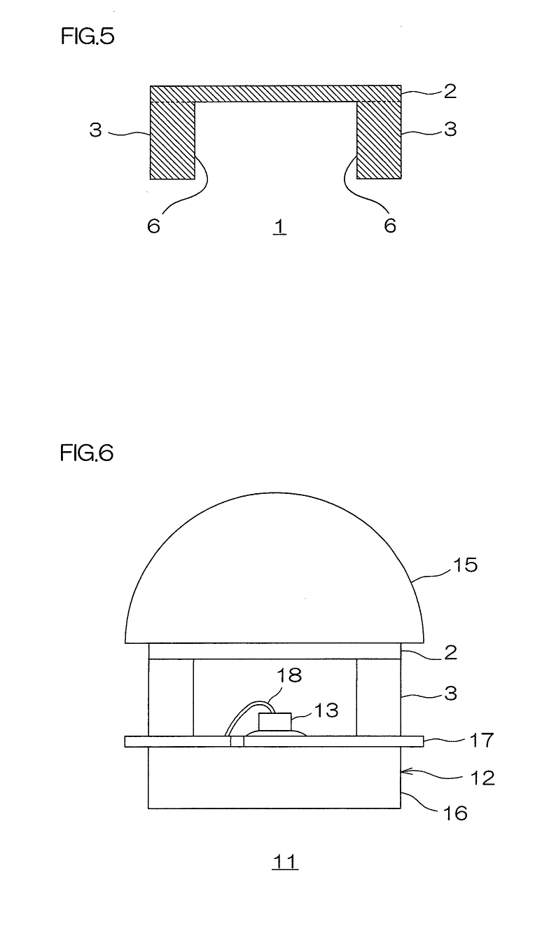

FIG. 5 shows a schematic configuration view of another embodiment of the component for a light-emitting device of the present invention.

In the above-described description, the fluorescent layer 2 is formed from the ceramic that contains the phosphor (phosphor ceramic) and the housing 3 is formed from the ceramic that does not contain the phosphor. However, for example, the housing 3 can also be formed from the ceramic that contains the above-described phosphor (phosphor ceramic).

That is, in this embodiment, as shown in FIG. 5, in the component 1 for a light-emitting device, the fluorescent layer 2 and the housing 3 are formed from the same material, that is, the ceramic that contains the phosphor (phosphor ceramic).

In the component 1 for a light-emitting device, two kinds of members, that is, the fluorescent layer 2 and the housing 3 can be formed from one kind of material (phosphor ceramic), so that the strength uniformity between each of the members can be achieved.

In this way, the ceramic that contains the phosphor (phosphor ceramic) can be used as the ceramic that forms the housing 3. However, the ceramic that does not contain the phosphor is preferably used.

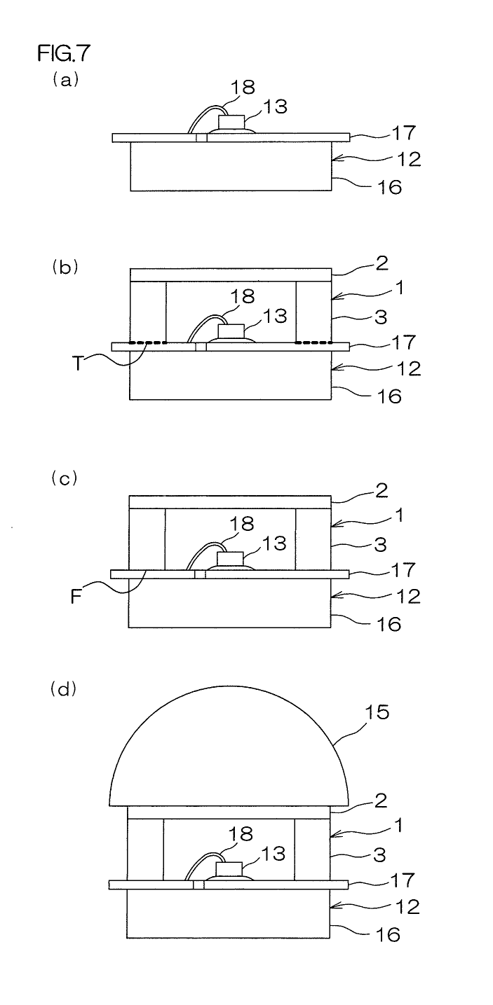

FIG. 6 shows a schematic configuration view of one embodiment of a light-emitting device of the present invention including the component for a light-emitting device shown in FIG. 1. FIG. 7 shows schematic process drawings for illustrating a method for producing the light-emitting device shown in FIG. 6.

In the following, the light-emitting device 11 including the above-described component 1 for a light-emitting device is described with reference to FIG. 6.

In FIG. 6, the light-emitting device 11 includes a circuit board 12, the light-emitting diode 13, and the above-described component 1 for a light-emitting device and is formed as a remote type light-emitting device in which the circuit board 12 and the light-emitting diode 13 are wire bonded to each other with the component 1 for a light-emitting device and the light-emitting diode 13 spaced apart from each other.

The circuit board 12 includes a base board 16 and a wiring pattern 17 formed on the upper surface of the base board 16. External electric power is supplied to the circuit board 12.

The base board 16 is formed into a generally rectangular flat plate shape in plane view and is formed from a metal such as aluminum, a ceramic such as alumina, a polyimide resin, and the like.

The wiring pattern 17 electrically connects a terminal of the light-emitting diode 13 to a terminal (not shown) of a power source (not shown) for supplying electric power to the light-emitting diode 13. The wiring pattern 17 is formed from a conductive material such as copper and iron.

As the circuit board 12, preferably, the reflectance of the region excluding the light-emitting diode 13 with respect to the light from the light-emitting diode 13 is set to be, for example, 70% or more, or preferably 90% or more, or more preferably 95% or more.

The light-emitting diode 13 is provided on the base board 16, for example, via a known solder and the like. The light-emitting diode 13 is electrically connected (wire bonding) to the wiring pattern 17 via a wire 18. The light-emitting diode 13 emits light based on electric power from the circuit board 12.

The component 1 for a light-emitting device is provided to stand upward from the upper surface of the base board 16 so that the upper end portion of the housing 3 is positioned above the upper end portion of the light-emitting diode 13. In addition, the component 1 for a light-emitting device is provided on the circuit board 12 so as to house the light-emitting diode 13 (and so that the housing 3 surrounds the light-emitting diode 13 in plane view).

In the component 1 for a light-emitting device, a filler such as a silicone resin and the like is filled in the housing 3 as required.

In addition, a lens 15 having a generally semi-sphere shape (generally dome shape) can be provided on the component 1 for a light-emitting device so as to cover the fluorescent layer 2 as required. The lens 15 is formed from, for example, a transparent resin such as a silicone resin.

In the following, a method for producing the above-described light-emitting device 11 is described with reference to FIG. 7.

In this method, as shown in FIG. 7 (a), the light-emitting diode 13 is first provided on the circuit board 12 to which external electric power is supplied and the light-emitting diode 13 is electrically connected to the circuit board 12 with the wire 18.

Next, in this method, as shown in FIG. 7 (b), the screening for non-defective products or defective products is performed by temporarily fixing the component 1 for a light-emitting device on the circuit board 12 (ref: T in FIG. 7) so as to house the light-emitting diode 13 and so that the upper end portion of the housing 3 is positioned above the upper end portion of the light-emitting diode 13, to examine the optical characteristics.

At this time, the inside of the housing 3 can be filled with the filler as required. In this case, though the details are not shown, for example, the component 1 for a light-emitting device is first placed so that the fluorescent layer 2 is directed downward in the vertical direction. Next, the filler is filled in the portion that is surrounded by the housing 3 and the fluorescent layer 2 of the component 1 for a light-emitting device. Thereafter, the circuit board 12 is put on the component 1 for a light-emitting device so that the light-emitting diode 13 is directed downward in the vertical direction and subsequently the component 1 for a light-emitting device covered with the circuit board 12 is flipped up and down in the vertical direction.

In this way, the inside of the housing 3 can be filled with the filler with excellent workability.

A method for temporary fixing is not particularly limited. For example, just a placing may be allowed and furthermore, a known adhesive resin may be placed between the circuit board 12 and the component 1 for a light-emitting device and thereafter, the adhesive resin may be semi-cured, for example, by heating and the like.

Next, in this method, as shown in FIG. 7 (c), in the non-defective products selected in the above description, the component 1 for a light-emitting device is fixed by a known method (ref: F in FIG. 7).

A method for fixing is not particularly limited. For example, the placed component 1 for a light-emitting device can be fixed by heating and furthermore, for example, when the known adhesive resin is placed between the circuit board 12 and the component 1 for a light-emitting device and the adhesive resin is semi-cured as described above, the adhesive resin may be further heated to be completely cured.

The light-emitting device 11 can be obtained in this manner.

In this method, as shown in FIG. 7 (d), the lens 15 can be provided on the fluorescent layer 2 of the component 1 for a light-emitting device as required.

In the light-emitting device 11, for example, a near-ultraviolet light-emitting diode, a blue light-emitting diode, and the like are used as the light-emitting diode 13 and by using the fluorescent layer 2 that generates fluorescent light by using the light from the light-emitting diode 13 as an exciting light, those lights can be color mixed, for example, to be able to obtain the light-emitting device 11 (white light-emitting diode) that generates white light.

In the light-emitting device 11, one component 1 for a light-emitting device is provided corresponding to one light-emitting diode 13.

When one component 1 for a light-emitting device is provided corresponding to one light-emitting diode 13, the light that one light-emitting diode 13 emits can be efficiently dispersed and/or reflected by one housing 3, so that excellent scattering efficiency and/or reflection efficiency can be ensured.

In the light-emitting device 11, the combination of the light-emitting diode 13 and the fluorescent layer 2 (combination of color mixing) is not limited to the above description and can be appropriately selected in accordance with the necessity and the use.

For example, by using a blue light-emitting diode as the light-emitting diode 13 and using the fluorescent layer 2 that produces green fluorescent light by using the light from the light-emitting diode 13 as an exciting light, the light-emitting device 11 that produces green light (green light-emitting diode) can be obtained. Furthermore, the light-emitting device 11 that generates a variety of lights such as pastel colors can be obtained by using the fluorescent layer 2 that produces other lights.

In the above-described embodiment, the light-emitting device 11 that has one light-emitting diode 13 is formed. However, the number of the light-emitting diode 13 provided on the light-emitting device 11 is not particularly limited and the light-emitting device 11 can be formed, for example, in a state of array in which a plurality of the light-emitting diodes 13 are arranged planarly (two-dimensionally) or linearly (one-dimensionally).

In the above-described embodiment, the remote type light-emitting device is produced. However, for example, a flip-chip type light-emitting device can be produced.

In the above-described embodiment, the lens 15 having a generally semi-sphere shape is provided on the fluorescent layer 2. However, for example, a micro-lens array sheet or a diffusing sheet can be provided instead of the lens 15.

When the above-described component 1 for a light-emitting device is manufactured industrially, for example, a housing sheet in which a plurality of the housings 3 are formed and a fluorescent layer sheet in which a plurality of the fluorescent layers 2 are formed are produced, respectively. The sheets are laminated and thereafter by dividing those, the component 1 for a light-emitting device including one housing 3 and one fluorescent layer 2 can be produced.

In the light-emitting device 11, the above-described component 1 for a light-emitting device is used.

Therefore, according to the producing method of the light-emitting device 11 and the light-emitting device 11 obtained by the method, the step of separately building up the fluorescent layer 2 and the housing 3 is not necessary, so that the light-emitting device 11 can be easily produced.

In addition, even when the light-emitting device 11 is screened as a defective product, it is possible to remove the temporarily fixed component 1 for a light-emitting device from the light-emitting device 11 to be discarded. Furthermore, the removed component 1 for a light-emitting device can be reused, so that an excellent yield rate can be ensured and the production costs can be reduced.

### EXAMPLES

While in the following, the present invention is described based on Examples, the present invention is not limited to any of them by no means.

### Example 1

### (1) Preparation of Phosphor (Material Particles) (Preparation of YAG:Ce Phosphor)

The components described below were dissolved in 250 ml of distilled water to prepare 0.4 M of a precursor solution. The details of the components were as follows: 0.14985 mol (14.349 g) of yttrium nitrate hexahydrate, 0.25 mol (23.45 g) of aluminum nitrate nonahydrate, and 0.00015 mol (0.016 g) of cerium nitrate hexahydrate.

The precursor solution was sprayed and pyrolyzed at a speed of 10 ml/min in radio frequency (RF) induction plasma flame using a two-fluid nozzle to obtain inorganic powder particles (material particles).

When the obtained material particles were analyzed by an X-ray diffraction method, a mixed phase of amorphous phase and YAP(YAlO₃) crystal was shown.

The average particle size thereof measured by a BET (Brunauer-Emmett-Teller) method using an automatic specific surface area analyzer (manufactured by Micrometritics Instrument Corp., model Gemini 2365) was about 75 nm.

Next, the obtained material particles were put in a crucible made of alumina and were temporarily calcined at 1200° C. for two hours in an electric furnace to obtain a YAG:Ce phosphor. The crystal phase of the obtained YAG:Ce phosphor showed a single phase of YAG. The average particle size thereof measured by the BET method was about 95 nm.

The melting point of the obtained YAG:Ce phosphor was 1900° C.

### (2) Production of Ceramic Green Sheet Laminate of YAG

The components described below with respect to 20 g of the YAG:Ce phosphor (the average particle size of 95 nm) were put in a vessel made of alumina, added with an yttrium stabilized zirconia ball in 3 mm, and wet blended at a speed of 1500 rpm for 24 hours with the ball mill, thereby preparing a slurry solvent of the YAG:Ce phosphor. The details of the components were as follows: 1.2 g of PVB (manufactured by Sigma-Aldrich Co., poly(vinyl butyral-co-vinyl alcohol-co-vinyl acetate) as a binder resin; 0.4 g of FlowlenG-700 (manufactured by KYOEISHA CHEMICAL CO., LTD) as a dispersant; 0.6 g of BBP (manufactured by Alfa Aesar, benzyl n-butyl phthalate) and 0.6 g of PEG (manufactured by Sigma-Aldrich Co., polyethylene glycol, molecular weight=400) as a plasticizer; 0.1 g of TEOS (manufactured by FLUKA TEAM, tetraethoxysilane) as a sintering additive of YAG ceramic; and 6 ml of xylene and 6 ml of methanol as a solvent.

Thereafter, the obtained slurry solvent was tape casted on a PET (polyethylene terephthalate) film by a doctor blade method and then was peeled off from the PET film after being dried naturally, thereby producing a ceramic green sheet. The thickness of the ceramic green sheet was controlled by adjusting a gap of the doctor blade.

Then, the obtained green sheet was cut out in the size of 20 mm×20 mm to obtain a plurality of pieces. The pieces were stacked (the laminating thickness: 320 μm) so as to become a desired thickness after the sintering and then were thermal laminated at the temperature of 90° C. using a biaxial hot press, thereby producing a ceramic green sheet laminate of YAG (20 mm×20 mm).

Furthermore, a ceramic green sheet having a thickness of more than 200 μm tends to have a crack and a wave on the surface when a solvent dries, so that the production thereof is difficult. Therefore, two or more of the same kinds of pieces were stacked so as to obtain a necessary sheet thickness, so that the necessary sheet thickness thereof was obtained.

### (3) Production of Ceramic Green Sheet Laminate of Aluminum Oxide

A ceramic green sheet laminate of aluminum oxide (20 mm×20 mm) was produced in the same manner as in <(2) Production of Ceramic Green Sheet Laminate of YAG> except that aluminum oxide particles (99.99% purity, part number: AKP-30, the melting point: 2020° C., manufactured by Sumitomo Chemical Co., Ltd.) were used instead of the YAG:Ce phosphor (the average particle size of 95 nm). The thickness of the laminate (the laminating thickness) was 500 μm.

Thereafter, the obtained green sheet (20 mm×20 mm) was cut with a CO₂ laser cutter (manufactured by Universal Laser Systems, Inc., VersaLASER VLS2.30) so that holes in the size of 2 mm×2 mm were formed at 2 mm intervals.

### (4) Production of Component for Light-emitting Device

The ceramic green sheet (laminate) of YAG obtained in <(2) Production of Ceramic Green Sheet Laminate of YAG> and the ceramic green sheet (laminate) of aluminum oxide in which a plurality of holes in the size of 2 mm×2 mm were formed obtained in <(3) Production of Ceramic Green Sheet Laminate of Aluminum Oxide> were stacked to be thermal laminated at the temperature of 90° C. using a biaxial hot press, thereby producing a ceramic green sheet laminate.

Thereafter, the obtained ceramic green sheet laminate was cut with a laser cutter, thereby producing a formed product in the size of 4 mm×4 mm (including a hole in the size of 2 mm×2 mm at the center).

The obtained formed product was heated up to 800° C. at the temperature rising speed of 1° C./min in the air in an electric muffle furnace to decompose and remove an organic component such as a binder resin (binder-removing treatment).

Thereafter, a sample (the formed product) was transferred into a high-temperature vacuum furnace and was heated up to 1600° C. at the temperature rising speed of 5° C./min in a vacuum of about 10⁻³ Torr to be calcined for five hours at the temperature, so that a component for a light-emitting device was obtained.

The obtained component for a light-emitting device shrank by about 20%, in both thickness and size, compared to the size of the ceramic green sheet due to densification by sintering.

### (5) Production of Light-emitting Diode (LED) Device for Evaluation

A blue LED chip (manufactured by Cree, Inc., part number: C450EX1000-0123, 980 μm×980 μm in size, chip thickness of about 100 μm) was mounted in the center on a commercially available printed wiring board made of aluminum having a size of 10 mm×20 mm and a thickness of 1.5 mm, thereby producing a blue LED device (ref: FIG. 7 (a)).

The wiring pattern was formed of Cu whose surface was protected with Ni/Au. The blue LED chip was die bonded on the wiring pattern with a silver paste and an opposing electrode was wire bonded on the wiring pattern using a gold wire.

Next, the component for a light-emitting device obtained in <(4) Production of Component for Light-emitting Device> was placed so that the fluorescent layer (formed product made of ceramic green sheet of YAG) was directed downward in the vertical direction. Then, a gel-like silicone resin (manufactured by WACKER ASAHIKASEI SILICONE CO., LTD., product name: WACKER SilGel 612) was casted into a mold composed of the fluorescent layer and a housing (formed product made of ceramic green sheet of aluminum oxide). Thereafter, a blue LED device was provided (temporarily fixed) from the upper surface to examine the optical characteristics. It was confirmed to be a non-defective product (ref: FIG. 7 (b)).

Thereafter, the component for a light-emitting device was fixed by being heated at 100° C. for 15 minutes on a hot plate (ref: FIG. 7 (c)). The light-emitting device was produced in this manner.

### Example 2

A light-emitting device was produced in the same manner as in Example 1 except that in <(3) Production of Ceramic Green Sheet Laminate of Aluminum Oxide>, YAG:Ce particles were used (that is, a ceramic green sheet laminate of YAG was produced) instead of aluminum oxide particles.

### Example 3

A ceramic green sheet laminate of YAG was produced in the same manner as in <(2) Production of Ceramic Green Sheet Laminate of YAG> and a fluorescent layer (phosphor plate) was produced in the same manner as in <(4) Production of Component for Light-emitting Device> of Example 1. In addition, a ceramic green sheet laminate of aluminum oxide was not produced.

A solvent in which barium titanate particles (manufactured by SAKAI CHEMICAL INDUSTRY CO., LTD., part number: BT-03) as scattering particles were dispersed into a two-liquid mixed type thermosetting silicone elastomer (manufactured by Shin-Etsu Chemical Co., Ltd., part number: KER 2500) at the proportion of 40 weight % was coated on a PET film with a thickness of about 500 μm using an applicator to be heated at 100° C. for one hour and at 150° C. for one hour, thereby producing a reflector resin sheet.

The reflector resin sheet was formed into a size whose outer diameter was 3.2 mm×3.2 mm and inner diameter was 1.6 mm×1.6 mm with a laser cutter. The formed reflector resin was attached to the fluorescent layer (phosphor plate) to be integrated by the above-described silicone elastomer. A light-emitting device was produced in the same manner as in <(5) Production of Light-emitting Diode (LED) Device for Evaluation> of Example 1 using the obtained laminate in this way.

### Evaluation

### (1) Measurement of Light-Emitting Characteristics in Light-Emitting Device

For the light-emitting devices obtained in each Examples, the angular dependent emission spectrum of the obtained light-emitting device was measured in the range of wavelength of 380 nm to 1000 nm with an optical fiber of a multi channel photo detector (manufactured by Otsuka Electronics Co., Ltd., MCPD 7000). A direct current of 100 mA was applied to the above-described blue LED device to be lit up.

The emission spectrum was recorded more than 10 seconds later after the electric power supply for performance stabilization of the blue LED device. The values of CIE chromaticity (x, y) at an angle of 0°, 45°, and 75° of the blue LED device were calculated from the obtained emission spectrum.

### (2) Temperature Measurement on Fluorescent Layer

In the light-emitting devices obtained in each Examples, the surface temperature of the fluorescent layer, when applying an electric current of 1 A to the blue LED device, was measured using an infrared camera (manufactured by FLIR Systems, Inc., product name: Infrared Camera A325).

TABLE 1

| | | | | Surface Temperature (°) of |
|---|---|---|---|---|
| | CIE chromaticity (x, y) | | | fluorescent layer when applying an |
| Example No. | 0° | 45° | 75° | electric current of 1 A |
| Example 1 | (0.31, 0.35) | (0.31, 0.35) | (0.31, 0.35) | 77 |
| Example 2 | (0.31, 0.35) | (0.34, 0.40) | (0.34, 0.41) | 76 |
| Example 3 | (0.31, 0.35) | (0.31, 0.35) | (0.31, 0.35) | 142 |

### (Consideration)

White light emission was confirmed in the light-emitting devices of Examples 1 to 3.

Above all, it was confirmed that in the light-emitting devices whose surfaces were entirely made of ceramic of Examples 1 and 2, even though lit up with a high driving current (1 A), the surface temperature of the fluorescent layers was low and the light-emitting devices had performance fully capable of being used as a high-power LED.

In addition, it was confirmed that in the light-emitting device of Example 2, the housing contained the phosphor, so that yellow became strong in an oblique direction, and therefore there was great variability in color depending on angles.

On the other hand, in the light-emitting device of Example 3, the mold frame was formed from a silicone resin whose thermal conductivity was low (thermal conductivity of about 2 W/m·K), so that the heat generated from the phosphor was not diffused through a package and reached 100° C. or more.

While the illustrative embodiments of the present invention are provided in the above description, such is for illustrative purpose only and it is not to be construed as limiting the scope of the present invention. Modification and variation of the present invention that will be obvious to those skilled in the art is to be covered by the following claims.

What is claimed is:

1. A component for a light-emitting device comprising:
a fluorescent layer that is capable of emitting fluorescent light; and
a housing that is connected to the fluorescent layer for housing a light-emitting diode.

2. The component for a light-emitting device according to claim 1, wherein
the fluorescent layer is made of a ceramic that contains a phosphor, and
the housing is made of a ceramic that does not contain a phosphor.

3. The component for a light-emitting device according to claim 1, wherein
the melting point of the ceramic material forming the housing is higher than that of the ceramic material forming the fluorescent layer.

4. A light-emitting device comprising:
a component for a light-emitting device comprising
a fluorescent layer that is capable of emitting fluorescent light; and
a housing that is connected to the fluorescent layer for housing a light-emitting diode.

5. The light-emitting device according to claim 4, wherein
a circuit board to which external electric power is supplied,
a light-emitting diode that is electrically connected onto the circuit board and emits light based on electric power from the circuit board,
the component for a light-emitting device provided on the circuit board so as to house the light-emitting diode, and wherein
the upper end portion of the housing is positioned above the upper end portion of the light-emitting diode.

6. A method for producing a light-emitting device comprising the steps of:
electrically connecting a light-emitting diode onto a circuit board to which external electric power is supplied;
screening for non-defective products or defective products by temporarily fixing, on the circuit board, a component for a light-emitting device including a fluorescent layer that is capable of emitting fluorescent light and a housing that is connected to the fluorescent layer for housing a light emitting diode so as to house the light-emitting diode and so that the upper end portion of the housing is positioned above the upper end portion of the light-emitting diode, to examine the optical characteristics; and
fixing the screened non-defective component for a light-emitting device.
